(19) United States
(12) Patent Application Publication
(10) Pub. No.: US 2012/0187521 A1
(43) Pub. Date: Jul. 26, 2012

(54) SCHOTTKY DIODE HAVING A SUBSTRATE P-N DIODE

(76) Inventors: Ning Qu, Reutlingen (DE); Alfred Goerlach, Kusterdingen (DE)

(21) Appl. No.: 13/388,651

(22) PCT Filed: Jun. 10, 2010
(86) PCT No.: PCT/EP2010/058168

§ 371 Date: Apr. 13, 2012

(30) Foreign Application Priority Data
Aug. 5, 2009 (DE) 10 2009 028 241.6

(51) Int. Cl. H01L 27/07; H01L 21/822

(52) U.S. Cl. 257/476; 438/570; 257/E27.044; 257/E21.606

(57) ABSTRACT

A semiconductor device has a trench junction barrier Schottky diode that includes an integrated substrate p-n diode (TJBS-Sub-PN) as a clamping element, the trench junction barrier Schottky diode being suited, e.g., as a Zener diode having a breakdown voltage of approximately 20 V, for use in motor-vehicle generator systems. In this context, the TJBS-Sub-PN is made up of a combination of a Schottky diode, an epitaxial p-n diode and a substrate p-n diode, and the breakdown voltage of the substrate p-n diode (BV_pn) is less than the breakdown voltage of the Schottky diode (BV_schottky) and the breakdown voltage of the epitaxial p-n diode (BV_epi).

### BACKGROUND OF THE INVENTION

1. Field of the Invention

The present invention relates to a trench junction barrier Schottky diode having an integrated substrate p-n diode as a clamping element (referred to below in simplified terms as TJBS-Sub-PN), which is suitable, e.g., as a power Zener diode having a breakdown voltage of approximately 20 V for use in motor-vehicle generator systems.

2. Description of Related Art

In modern motor vehicles, more and more functions are implemented by electrical components. This creates a continuously increasing requirement for electrical power. In order to satisfy this requirement, the efficiency of the generator system in the motor vehicle must be increased. To this day, p-n diodes have normally been used as Zener diodes in motor-vehicle generator systems. Advantages of p-n diodes include, on one hand, the low reverse current and, on the other hand, the high degree of robustness. The main disadvantage is the high forward voltage UF. At room temperature, current only begins to flow at UF=0.7 V. Under normal operating conditions, for instance, at a current density of 500 A/cm², UF increases to greater than 1 V, which means a non-negligible loss of efficiency.

In theory, Schottky diodes are available as an alternative. Schottky diodes have a markedly lower forward voltage than p-n diodes, for example, 0.5 V to 0.6 V at a high current density of 500 A/cm². In addition, Schottky diodes, as majority carrier components, offer advantages in rapid switching operation. However, at present, Schottky diodes are not yet used in motor-vehicle generator systems. This may be attributed to a few crucial disadvantages of Schottky diodes: 1) higher reverse current in comparison with p-n diodes, 2) strong dependence of the reverse current on the reverse voltage, and 3) poor robustness, especially at high temperatures.

There are known proposals for improving Schottky diodes. Two examples are explained below.

1. JBS junction barrier Schottky diodes are described in Kozaka, Hiroshi et al., “Low leakage current Schottky barrier diode,” Proceedings of 1992 International Symposium on Power Semiconductors & ICs, Tokyo, pp. 80-85. As shown in FIG. 1, the JBS is made up of an n⁺-substrate 1, an n-epitaxial layer 2, at least two p-wells 3 diffused into n-epitaxial layer 2, and metallic layers on the front side 4 and on the back side 5 of the chip. From an electrical standpoint, the JBS is a combination of a p-n diode (p-n junction between p-wells 3 as an anode and n-epitaxial layer 2 as a cathode) and a Schottky diode (Schottky barrier between metallic layer 4 as an anode and n-epitaxial layer 2 as a cathode). The metallic layer on the back side of the chip 5 is used as a cathode electrode; the metallic layer on the front side of the chip 4 is used as an anode electrode having an ohmic contact with p-wells 3 and, simultaneously, as a Schottky contact with n-epitaxial layer 2.

Due to the low forward voltage of the Schottky diode in comparison with the p-n diode, currents flow in the forward direction only through the region of the Schottky diode. Consequently, the effective surface (per unit surface area) for the flow of current in the forward direction in a JBS is markedly smaller than in a conventional planar Schottky diode. In the reverse direction, the space charge regions expand with increasing voltage, and in the event of a voltage that is less than the breakdown voltage of the JBS, the space charge regions impinge upon one another in the middle of the region between adjacent p-wells 3. In this manner, the Schottky effect, which is responsible for the high reverse currents, is partially blocked, and the reverse current is reduced. This blocking effect is highly dependent on structural parameters Xjp (penetration depth of the p-diffusion), Wn (distance between the p-wells), as well as Wp (width of the p-well).

P-implantation and subsequent p-diffusion are customary for producing the p-wells of a JBS. Due to lateral diffusion in the x direction, whose depth is comparable to the vertical diffusion in the y direction, cylindrical p-wells are formed in the two-dimensional representation (infinite length in the z direction perpendicular to the x-y plane), the radius of the cylindrical p-wells corresponding to penetration depth Xjp. Because of the radial extension of the space charge regions, this shape of p-wells does not produce a highly effective blocking-out of the Schottky effect. It is not possible to strengthen the blocking effect by deeper p-diffusion alone, since the lateral diffusion simultaneously becomes correspondingly wider, as well. It is also questionable to decrease the distance between the p-wells Wn. To be sure, this increases the blocking effect, but the effective area for the flow of current in the forward direction is further reduced.

An alternative for improving the effectiveness of blocking the Schottky effect (barrier lowering effect) of a JBS is the TJBS proposed in published German patent application document DE 10 2004 053 761. A TJBS (trench junction barrier Schottky diode) having filled-in trenches is described in FIG. 2. As shown by FIG. 2, this TJBS variant is made up of an n⁺-substrate 1, an n-epitaxial layer 2, at least two trenches 6 etched into n-epitaxial layer 2 and metallic layers on the front side of the chip 4 as an anode electrode, and on the back side of the chip 5 as a cathode electrode. The trenches are filled in with p-doped Si or poly-Si 7. In particular, metallic layer 4 may also be made up of a plurality of different, superposed metallic layers. For the sake of clarity, this is not drawn into FIG. 2. From an electrical standpoint, the TJBS is a combination of a p-n diode (p-n junction between p-doped trenches 7 as an anode and n-epitaxial layer 2 as a cathode) and a Schottky diode (Schottky barrier between metallic layer 4 as an anode and n-epitaxial layer 2 as a cathode).

As in a conventional JBS, currents flow in the forward direction only through the Schottky diode. However, because lateral p-diffusion is absent, the effective area for the flow of current in the forward direction is markedly greater in the TJBS than in a conventional JBS.

In the reverse direction, the space charge regions expand with increasing voltage, and in the event of a voltage that is less than the breakdown voltage of the TJBS, the space charge regions impinge upon one another in the middle of the region between adjacent trenches 6. As in the JBS, this blocks off the Schottky effect responsible for high reverse currents, and reduces the reverse currents. This blocking effect is highly dependent on structural parameters Dt (depth of the trench), Wm (distance between the trenches) and Wt (width of the trench); see FIG. 2.

The p-diffusion is not used to produce the trenches in the TJBS. As a result, there is no negative effect of lateral p-diffusion, as in a conventional JBS. A quasi-one dimensional expansion of the space charge regions in the mesa region between trenches 6 may easily be implemented, since depth of the trench Dt, an important structural parameter for the blocking of the Schottky effect, no longer correlates with the effective area for the flow of current in the forward direction. Therefore, the action of blocking Schottky effects is markedly more effective than in the case of the JBS having diffused p-wells.

On the other hand, the TJBS provides a high degree of robustness through its clamping function. Breakdown voltage of the p-n diode BV_pn is specified in such a manner, that BV_pn is lower than breakdown voltage of the Schottky diode BV_schottky and the breakdown takes place at the base of the trenches. Then, in breakdown operation, the reverse current only flows through the p-n junction. Consequently, the forward direction and reverse direction are geometrically separated. Thus, the TJBS has a robustness similar to a p-n diode. In addition, the injection of “hot” charge carriers does not occur in a TJBS, since no MOS structure exists. Consequently, the TJBS is well-suited as a Zener diode for use in a motor-vehicle generator system.

### BRIEF SUMMARY OF THE INVENTION

According to the present invention, Schottky diodes having a low reverse current, lower forward voltage, greater robustness and simpler process control shall be provided, which are suited for use as power Zener diodes in motor-vehicle generator systems.

The Schottky diode of the present invention advantageously includes a TJBS having an integrated substrate p-n diode as a clamping element and is referred to below in simplified terms as “TJBS-Sub-PN.” The trenches extend up to the n⁺-substrate and are filled in with p-doped Si or poly-Si. The breakdown voltage of the TJBS-Sub-PN is determined by the p-n junction between the p-wells (the trenches filled in with p-doped Si or poly-Si) and the n⁺-substrate. In this context, the layout of the p-wells is selected so that breakdown voltage of the substrate p-n diode BV_sub is less than breakdown voltage of the Schottky diode BV_schottky and breakdown voltage of the epitaxial p-n diode BV_epi. In comparison with the conventional JBS, it is particularly advantageous that markedly lower reverse currents occur due to effective blocking of the Schottky effect, and that a markedly greater effective area for the flow of current in the forward direction is present. In comparison with the TJBS, a lower forward voltage is obtained due to a thinner epitaxial layer having lower bulk resistance.

### BRIEF DESCRIPTION OF THE DRAWINGS

FIG. 1 shows a known JBS (junction barrier Schottky diode).

FIG. 2 shows a known TJBS (trench junction barrier Schottky diode) having a filled-in trench.

FIG. 3 shows a TJBS-sub-PN having filled-in trenches.

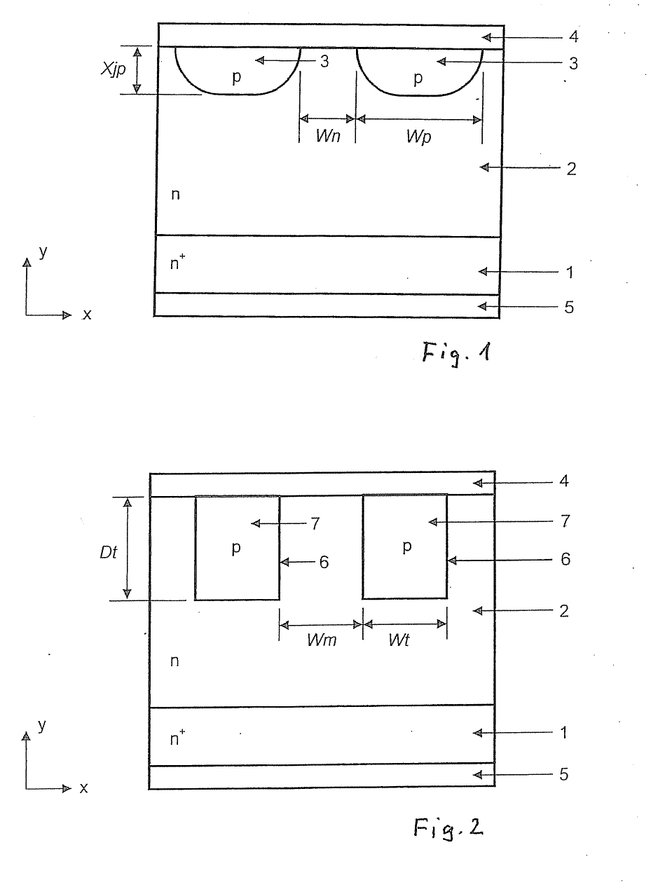

### DETAILED DESCRIPTION OF THE INVENTION

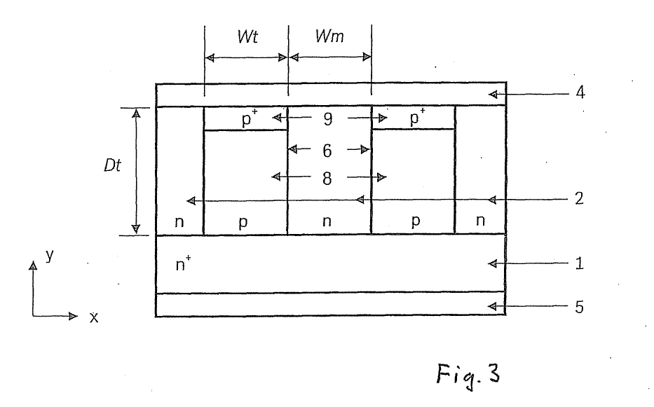

As shown in FIG. 3, the TJBS-Sub-PN of the present invention is made up of an n⁺-substrate 1, an n-epitaxial layer 2, at least two trenches 6 that are etched through epitaxial layer 2 up to n⁺-substrate 1 and have a width Wt, a depth Dt and a distance Wm between adjacent trenches 6, and metallic layers on the front side of the chip 4 in the form of an anode electrode and on the back side of the chip 5 in the form of a cathode electrode. Trenches 6 are filled in with p-doped Si or poly-Si 8, and additional, thin p⁺-layers 9 are situated in the upper regions of the trenches to provide ohmic contacts with metallic layer 4. In some instances, thin p⁺-layers 9 may also be somewhat recessed, so that they are situated completely within p-doped layers 8.

In electrical terms, the TJBS-Sub-PN is a combination of a Schottky diode (Schottky barrier between metallic layer 4 as an anode and n-epitaxial layer 2 as a cathode), an epitaxial p-n diode (p-n junction between the p-wells (the trenches filled in with p-doped Si or poly-Si 8) as an anode and n-epitaxial layer 2 as a cathode), and a substrate p-n diode (p-n junction between p-wells 8 as an anode and n⁺-substrate 1 as a cathode). The p-trenches 8 are designed so that the breakdown voltage of the TJBS-Sub-PN is determined by the breakdown voltage of the p-n junction between p-wells 8 and n⁺-substrate 1.

As in the case of a conventional JBS or TJBS, in the TJBS-Sub-PN, currents flow in the forward direction only through the Schottky diode if the forward voltage of the TJBS-Sub-PN is markedly less than the forward voltage of the substrate p-n diode. In the Schottky diode, the epitaxial p-n diode and the substrate p-n diode, space charge regions form in the reverse direction. The space charge regions expand with increasing voltage in both n-epitaxial layer 2 and p-wells 8, and in the event of a voltage that is less than the breakdown voltage of the TJBS-Sub-PN, the space charge regions impinge upon one another in the middle of the region between adjacent trenches 6. In this manner, the Schottky effects (barrier lowering effect) responsible for high reverse currents are blocked and the reverse currents are reduced. This blocking effect is predominantly determined by the epitaxial p-n structure and strongly dependent on structural parameters Dt (depth of the trench), Wm (distance between the trenches) and Wt (width of the trench), as well as on doping concentrations of p-well 8 and of n-epitaxial layer 2; see FIG. 3.

The TJBS-Sub-PN has an action of blocking Schottky effects that is similar to a TJBS, and, like a TJBS, offers a high degree of robustness through the clamping function. Breakdown voltage of the substrate p-n diode BV_pn is designed so that BV_pn is less than breakdown voltage of the Schottky diode BV_schottky and breakdown voltage of the epitaxial p-n diode BV_epi, and that the breakdown takes place at the substrate p-n junction between p-wells 8 and n⁺-substrate 1. Then, in breakdown operation, reverse currents only flow through the substrate p-n junction. Thus, the TJBS-Sub-PN has a robustness similar to a p-n diode.

In comparison with the TJBS, the TJBS-Sub-PN of the present invention exhibits a lower forward voltage, since the breakdown voltage of the TJBS-Sub-PN is not determined by the p-n junction between the p-wells and the n-epitaxial layer (FIG. 2), but by the substrate p-n junction between the p-wells and the n⁺-substrate (see FIG. 3). The part of the n-epitaxial layer that is present in the TJBS and is between the p-region and n⁺-substrate is omitted. Thus, the entire n-epitaxial layer thickness and, consequently, the bulk resistance for achieving the same breakdown voltage is smaller in the case of the TJBS-Sub-PN. This has an advantageous effect for operation in the forward direction (lower forward voltage).

A further advantage of the TJBS-Sub-PN over the TJBS is the considerably simpler process control. A possible method for manufacturing the TJBS-Sub-PN includes the following steps:
n⁺-substrate as a starting material
n-epitaxy
trench etching up to the n⁺-substrate
filling in the trenches with p-doped Si or poly-Si
diffusion of a thin p⁺-layer in the upper region of the trenches
metallization on the front and back sides

In the TJBS-Sub-PN, the edge region of the chip may even have additional structures for reducing the marginal field intensity. These may include, for example, low-doped p-regions, magnetoresistors or similar structures corresponding to the related art.

The semiconductor materials and dopings selected in the description of the design approaches of the present invention are exemplary. In addition, in each instance, p-doping may be selected instead of n-doping, and n-doping may be selected instead of p-doping.

1-10. (canceled)

11. A semiconductor device, comprising:
a trench junction barrier Schottky diode which includes an integrated substrate p-n diode as a clamping element, wherein:
the trench junction barrier Schottky diode is in the form of a Zener diode having a breakdown voltage in the range of 20 V,
the trench junction barrier Schottky diode which includes the integrated substrate p-n diode is made up of at least a combination of a Schottky diode, an epitaxial p-n diode and the substrate p-n diode, and
the breakdown voltage of the substrate p-n diode is less than the breakdown voltage of the Schottky diode and the breakdown voltage of the epitaxial p-n diode.

12. The semiconductor device as recited in claim 11, wherein the semiconductor device is incorporated as a part of a motor-vehicle generator system.

13. The semiconductor device as recited in claim 11, wherein the semiconductor device is operable at high currents during breakdown.

14. The semiconductor device as recited in claim 11, wherein:
an n-epitaxial layer is situated on an n⁺-substrate and is used as a cathode region;
at least two trenches etched through the n-epitaxial layer up to the n⁺-substrate are present;
the at least two trenches are filled with one of p-doped Si or poly-Si and are used as an anode region of the substrate p-n diode; and
thin p⁺-layers are situated in upper regions of the at least two trenches.

15. The semiconductor device as recited in claim 14, wherein:
a first metallic layer is situated on the back side of the device and is used as a cathode electrode; and
a second metallic layer is (i) situated on the front side of the device, (ii) has an ohmic contact with the thin p⁺ layers, (iii) has a Schottky contact with the n-epitaxial layer, and (iv) used as an anode electrode.

16. The semiconductor device as recited in claim 14, wherein the at least two trenches are etched through the n-epitaxial layer up to the n⁺-substrate and have one of a rectangular shape or a U-shape.

17. The semiconductor device as recited in claim 15, wherein each of the first and second metallic layers is made up of at least two superposed component metallic layers.

18. The semiconductor device as recited in claim 14, wherein the at least two trenches are positioned one of in a strip arrangement or as islands, and wherein the islands are formed in the shape of one of a circle or a hexagon.

19. The semiconductor device as recited in claim 14, wherein a Schottky contact is made of one of nickel or nickel silicide.

20. A method for manufacturing a semiconductor device having a trench junction barrier Schottky diode which includes an integrated substrate p-n diode as a clamping element, comprising:
providing an n⁺-substrate as a starting material;
providing an n-epitaxial layer;
etching at least two trenches through the n-epitaxial layer up to the n⁺substrate;
filling the at least two trenches with one of p-doped Si or poly-Si;
providing a thin p⁺-layer by diffusion in the upper region of the at least two trenches; and
providing metallization on the front and back sides of the semiconductor device.
